(19) United States
(12) Patent Application Publication
(10) Pub. No.: US 2026/0310078 A1
(43) Pub. Date: Oct. 8, 2026

(54) NEGATIVE RESIST COMPOSITION AND METHOD FOR PRODUCING RESIST PATTERN

(71) Applicant: SUMITOMO CHEMICAL COMPANY, LIMITED, Tokyo (JP)

(72) Inventors: Suguru TANIGUCHI, Osaka (JP); Masako SUGIHARA, Osaka (JP)

(73) Assignee: SUMITOMO CHEMICAL COMPANY, LIMITED, Tokyo (JP)

(21) Appl. No.: 19/638,698

(22) Filed: Apr. 3, 2026

(30) Foreign Application Priority Data
Apr. 7, 2025 (JP) 2025-063087

(51) Int. Cl. G03F 7/038; C08F 8/02; G03F 7/16

(52) U.S. Cl. CPC G03F 7/0388; C08F 8/02; G03F 7/0382; G03F 7/168

(57) ABSTRACT

A negative resist composition capable of forming a resist pattern having a favorable shape is provided. In addition, a method for producing a resist pattern using the negative resist composition is provided.

A negative resist composition includes: a resin (A1) including a structural unit represented by a formula (a2-1) and a structural unit represented by a formula (a2-4); an acid generator (B); a crosslinking agent (E); and an aromatic compound (I) having a molecular weight of 2,000 or less and having three or more phenolic hydroxyl groups, and a method for producing a resist pattern using the composition.

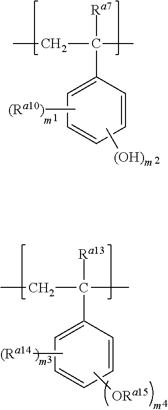

### BACKGROUND OF THE INVENTION

### Field of the Invention

The present invention relates to a negative resist composition and a method for producing a resist pattern.

### Description of the Related Art

JP-A-2001-42529 describes a negative resist composition containing a partially ethyl-etherified polyvinyl phenol and an m-cresol novolac resin.

### SUMMARY OF THE INVENTION

In the negative resist composition as described in JP-A-2001-42529, the shape of the obtained resist pattern may not be favorable because of the influence of standing waves due to reflection of exposure light from the substrate.

Therefore, an object of the present invention is to provide a negative resist composition capable of forming a resist pattern having a favorable shape. In addition, another object of the present invention is to provide a method for producing a resist pattern using the negative resist composition.

As a result of intensive studies to solve the above problem, the inventor has found that the above problem can be solved by providing a negative resist composition including a resin (A1), an acid generator (B), a crosslinking agent (E), and an aromatic compound (I), in which the aromatic compound (I) has a molecular weight of 2,000 or less and contains a compound having three or more phenolic hydroxyl groups. The present invention has been completed by further conducting studies.

That is, the present invention relates to the following negative resist composition and a method for producing a resist pattern using the composition.

[1]A negative resist composition including a resin (A1) including a structural unit represented by a formula (a2-1) and a structural unit represented by a formula (a2-4), an acid generator (B), a crosslinking agent (E), and an aromatic compound (I) having a molecular weight of 2,000 or less and having three or more phenolic hydroxyl groups, in which

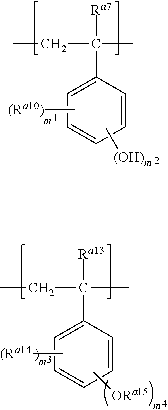

in the formula (a2-1) and the formula (a2-4),
R^{a7} and R^{a13} each independently represent a hydrogen atom or a methyl group,
R^{a10} and R^{a14} each independently represent an alkyl group having 1 to 6 carbon atoms,
R^{a15} represents a hydrocarbon group having 1 to 12 carbon atoms,
m′ represents an integer of 0 to 4, when m′ is 2 or more, a plurality of R^{a10} may be the same or different from each other,
m² represents an integer of 1 to 4,
provided that a sum of m¹ and m² is 5 or less,
m³ represents an integer of 0 to 4, when m³ is 2 or more, a plurality of R^{a14} may be the same or different from each other,
m⁴ represents an integer of 1 to 4, and when m⁴ is 2 or more, a plurality of R^{a15} may be the same or different from each other,
provided that a sum of m³ and m⁴ is 5 or less.

[2] The negative resist composition according to [1], in which the aromatic compound (I) is a compound represented by a formula (I0), in which

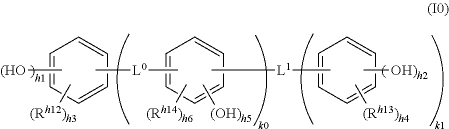

in the formula (I0),
L⁰ and L¹ each independently represent a hydrocarbon group having 1 to 20 carbon atoms and optionally having a substituent, and a methylene group included in the hydrocarbon group may be substituted with an oxygen atom or a carbonyl group,
R^{h12}, R^{h13}, and R^{h14} each independently represent a halogen atom or a hydrocarbon group having 1 to 20 carbon atoms and optionally having a substituent, or R^{h12} and R^{h13},
R^{h12}, and R^{h14}, R^{h13} and R^{h14}, or R^{h12}, R^{h13}, or R^{h14} and L⁰ or L¹ may be bonded to form a ring optionally having a substituent,
k0 represents an integer of 0 to 6, when k0 is 2 or more, a plurality of groups in parentheses may be the same or different from each other,
k1 represents an integer of 1 to 6, when k1 is 2 or more, a plurality of groups in parentheses may be the same or different from each other,
h1 and h2 each independently represent an integer of 0 to 5,
h5 represents an integer of 0 to 4,
h3 and h4 each independently represent an integer of 0 to 5, when h3 or h4 is 2 or more, a plurality of R^{h12} or R^{h13} may be the same or different from each other, and
h6 represents an integer of 0 to 4, when h6 is 2 or more, a plurality of R^{h14} may be the same or different from each other,
provided that a sum of h1, h2, and h5 is 3 or more, a sum of h1 and h3 is 5 or less, a sum of h2 and h4 is 5 or less, and a sum of h5 and h6 is 4 or less.

[3] The negative resist composition according to [1] or [2], in which the aromatic compound (I) is a compound represented by a formula (I1), in which

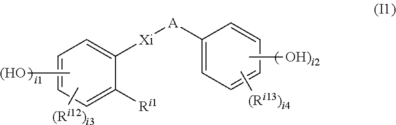

in the formula (I1),
Xi represents a single bond or an oxygen atom,
A represents an alkanediyl group having 1 to 6 carbon atoms and optionally having a substituent, and a methylene group included in the alkanediyl group may be substituted with an oxygen atom or a carbonyl group, provided that when Xi is an oxygen atom, a methylene group bonded to Xi is not substituted with an oxygen atom,
i1 and i2 each independently represent an integer of 0 to 4, provided that a sum of i1 and i2 is 3 or more,
Rⁱ¹² and Rⁱ¹³ each independently represent a halogen atom or an alkyl group having 1 to 12 carbon atoms and optionally having a substituent,
i3 and i4 each independently represent an integer of 0 to 4, when i3 or i4 is 2 or more, a plurality of Rⁱ¹² or Rⁱ¹³ may be the same or different from each other, and
Rⁱ¹¹ represents a hydrogen atom or an alkyl group having 1 to 12 carbon atoms and optionally having a substituent, or when A is an alkanediyl group, Rⁱ¹ may be bonded to A to form a ring optionally having a substituent,
provided that a sum of i1 and i3 is 4 or less, and a sum of i2 and i4 is 5 or less.

[4] The negative resist composition according to any one of [1] to [3], in which the crosslinking agent (E) is a glycoluril-based crosslinking agent.

[5]A method for producing a resist pattern, the method including:
(1) applying the negative resist composition according to any one of [1] to [4] onto a substrate;
(2) drying the applied composition to form a composition layer;
(3) exposing the composition layer; and
(4) heating and developing the exposed composition layer.

The present invention can provide a negative resist composition having a favorable resist pattern shape.

### BRIEF DESCRIPTION OF THE DRAWINGS

FIG. 1 is a view schematically illustrating a cross-sectional shape of a line-and-space in a resist pattern.

### DETAILED DESCRIPTION OF THE PREFERRED EMBODIMENTS

In the present specification, unless otherwise specified, in the description of the structural formula of the compound, the “hydrocarbon group” means a linear or branched chain hydrocarbon group, an alicyclic hydrocarbon group, an aromatic hydrocarbon group, or a group obtained by combining these groups. The “alicyclic hydrocarbon group” means a group in which hydrogen atoms of the number corresponding to the valence are removed from the ring of the alicyclic hydrocarbon. The “aromatic hydrocarbon group” also includes a group in which a chain hydrocarbon group and an alicyclic hydrocarbon group are bonded to an aromatic ring. When stereoisomers are present, all stereoisomers are included.

In the present specification, “(meth)acrylic acid” means “at least one of acrylic acid and methacrylic acid”, and “(meth)acrylate” means “at least one of acrylate and methacrylate”.

In the groups described in the present specification, those that can have both a linear structure and a branched structure are interpreted as meaning including both of them.

In the present specification, the “solid content of the negative resist composition” means the total of components obtained by removing a solvent (D) described later from the total amount of the negative resist composition.

### 1. Negative Resist Composition

The negative resist composition of the present invention contains a resin having a phenolic hydroxyl group (hereinafter, may be referred to as “resin (A1)”), an acid generator (hereinafter, may be referred to as an “acid generator (B)”), a crosslinking agent (hereinafter, may be referred to as a “crosslinking agent (E)”), and an aromatic compound having a molecular weight of 2,000 or less and having three or more phenolic hydroxyl groups (“hereinafter, may be referred to as “compound (I)” or “aromatic compound (I)”).

Further, the negative resist composition of the present invention may include a resin other than the resin (A1), a quencher (hereinafter, may be referred to as a “quencher (C)”), a solvent (hereinafter, may be referred to as a “solvent (D)”), and other components (hereinafter, may be referred to as “other components (F)”), as necessary.

In the negative resist composition of the present invention, examples of the resin other than the resin (A1) include alkali-soluble resins. The alkali-soluble resin is a resin having an acidic group (also referred to as a hydrophilic group) and soluble in an alkaline developer. The acidic group is, for example, a carboxy group, a sulfo group, a hydroxy group (phenolic hydroxyl group or the like), or the like.

Examples of the alkali-soluble resin include alkali-soluble resins known in the resist field, and include a novolak resin (hereinafter, may be referred to as a “novolac resin (A2)”), a resin including a structural unit (a2-1) but not including a structural unit (a2-4), a resin including a structural unit derived from a (meth)acrylic acid ester, and a polyalkylene glycol.

### <Resin (A1)>

The resin (A1) includes a structural unit having a phenolic hydroxyl group, and is preferably a resin including the structural unit (a2-1) and the structural unit (a2-4).

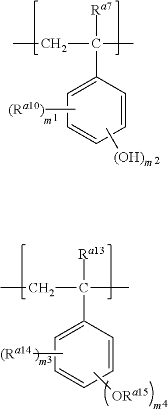

[In the formula (a2-1) and the formula (a2-4),
R^{a7} and R^{a13} each independently represent a hydrogen atom or a methyl group.
R^{a10} and R^{a14} each independently represent an alkyl group having 1 to 6 carbon atoms.
R^{a15} represents a hydrocarbon group having 1 to 12 carbon atoms,
m¹ represents an integer of 0 to 4, when m¹ is 2 or more, a plurality of R^{a10} may be the same or different from each other,
m² represents an integer of 1 to 4,
provided that a sum of m¹ and m² is 5 or less,
m³ represents an integer of 0 to 4, when m³ is 2 or more, a plurality of R^{a14} may be the same or different from each other,
m⁴ represents an integer of 1 to 4, and when m⁴ is 2 or more, a plurality of R^{a15} may be the same or different from each other,
provided that a sum of m³ and m⁴ is 5 or less.]

The hydrocarbon group having 1 to 12 carbon atoms represented by R^{a5} excludes a group in which a carbon atom bonded to an oxygen atom is a tertiary carbon atom. The methylene group included in the hydrocarbon group having 1 to 12 carbon atoms may be substituted with an oxygen atom or a carbonyl group. Provided that a methylene group bonded to an oxygen atom and a methylene group bonded to the methylene group in the formula (a2-4) are not substituted with an oxygen atom.

As R^{a15}, an alkyl group having 1 to 6 carbon atoms is preferable, an alkyl group having 1 to 4 carbon atoms is more preferable, and a methyl group, an ethyl group, and a propyl group are still more preferable.

In the resin (A1), the content of the structural unit (a2-1) is preferably 10 to 90 mol %, and more preferably 20 to 85 mol % based on the total structural units of the resin (A1).

In the resin (A1), the content of the structural unit (a2-4) is preferably 5 to 40 mol %, more preferably 10 to 30 mol %, still more preferably 15 to 30% based on the total structural units of the resin (A1).

The resin (A1) may include a structural unit other than the structural unit (a2-1) and the structural unit (a2-4). Examples of such a structural unit include a structural unit of a monomer in which a hydroxy group of hydroxystyrene is substituted with another group, and a structural unit of a monomer having an α, β-unsaturated double bond.

In addition, examples of the monomer forming such a structural unit include styrene-based monomers such as styrene, chlorostyrene, and α-methylstyrene, acrylic acid monomers such as acrylic acid, methacrylic acid, methyl acrylate, and methyl methacrylate, and vinyl acetate-based monomers such as vinyl acetate and vinyl benzoate.

The resin (A1) can be produced, for example, by a method as described in JP-A-7-295220.

The resin (A1) has a weight average molecular weight of preferably 1,000 or more, more preferably 1,500 or more, still more preferably 2,000 or more, and preferably 10,000 or less, more preferably 8,000 or less, still more preferably 5,000 or less. The weight average molecular weight is determined as a value in terms of standard polystyrene by gel permeation chromatography analysis. Detailed analytical conditions of this analysis are described in examples of the present application.

The content of the resin (A1) is preferably 10 mass % or more, more preferably 15 mass % or more, still more preferably 20 mass % or more, yet more preferably 30 mass % or more, further preferably 40 mass % or more, further more preferably 50 mass % or more, and preferably 100 mass % or less, based on the total amount of the resin included in the negative resist composition of the present invention.

### <Novolac Resin (A2)>

A novolac resin (A2) is a resin obtained by condensing a phenol compound and an aldehyde in the presence of a catalyst, and is, for example, a resin including a structural unit represented by a following formula (a4).

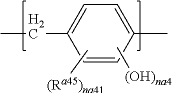

[In the formula (a4),
R^{a45} represents a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group.
na4 represents an integer of 1 to 4.
na41 represents an integer of 0 to 3, and when na41 is 2 or more, a plurality of R^{a45} may be the same or different from each other. Provided that 1≤na4+na41≤4 is satisfied.]

In the formula (a4), examples of the halogen atom as for R^{a45} include a fluorine atom, a chlorine atom, a bromine atom, and an iodine atom.

The alkyl group having 1 to 6 carbon atoms as for R^{a45} may be a linear or branched alkyl group, and examples thereof include a methyl group, an ethyl group, a propyl group, a butyl group, a pentyl group, and a hexyl group.

Examples of the haloalkyl group having 1 to 6 carbon atoms as for R^{a45} include a group in which a hydrogen atom included in the alkyl group is substituted with the halogen atom, and examples thereof include an alkyl fluoride group having 1 to 6 carbon atoms, an alkyl chloride group having 1 to 6 carbon atoms, an alkyl bromide group having 1 to 6 carbon atoms, and an alkyl iodide group having 1 to 6 carbon atoms, and among these, a perfluoroalkyl group having 1 to 3 carbon atoms is preferable.

Examples of the alkoxy group having 1 to 6 carbon atoms as for R^{a45} include a methoxy group, an ethoxy group, a propoxy group, an isopropoxy group, a butoxy group, a sec-butoxy group, and a tert-butoxy group. The number of carbon atoms of the alkoxy group is preferably 1 to 4 and more preferably 1 to 3, and the alkoxy group is still more preferably a methoxy group or an ethoxy group, and yet more preferably a methoxy group.

Examples of the alkoxyalkyl group having 2 to 12 carbon atoms as for R^{a45} include a methoxymethyl group, an ethoxyethyl group, a propoxymethyl group, an isopropoxymethyl group, a butoxymethyl group, a sec-butoxymethyl group, and a tert-butoxymethyl group. The alkoxyalkyl group is preferably an alkoxyalkyl group having 2 to 8 carbon atoms, more preferably a methoxymethyl group or an ethoxyethyl group, and still more preferably a methoxymethyl group.

Examples of the alkoxyalkoxy group having 2 to 12 carbon atoms as for R^{a45} include a methoxymethoxy group, a methoxyethoxy group, an ethoxymethoxy group, an ethoxyethoxy group, a propoxymethoxy group, an isopropoxymethoxy group, a butoxymethoxy group, a sec-butoxymethoxy group and a tert-butoxymethoxy group. The alkoxyalkoxy group is preferably an alkoxyalkoxy group having 2 to 8 carbon atoms, and more preferably a methoxyethoxy group or an ethoxyethoxy group.

Examples of the alkylcarbonyl group having 2 to 4 carbon atoms as for R^{a45} include an acetyl group, a propionyl group and a butyryl group. The alkylcarbonyl group is preferably an alkylcarbonyl group having 2 to 3 carbon atoms, and more preferably an acetyl group.

Examples of the alkylcarbonyloxy group having 2 to 4 carbon atoms as for R^{a45} include an acetyloxy group, a propionyloxy group and a butyryloxy group. The alkylcarbonyloxy group is preferably an alkylcarbonyloxy group having 2 to 3 carbon atoms, and more preferably an acetyloxy group.

In the formula (a4), R⁴⁵ is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group, or an ethoxy group, and yet more preferably a methyl group or a methoxy group.
na4 is preferably 1 or 2, and more preferably 1.
na41 is preferably 0, 1, or 2, and more preferably 0 or 1.

The novolac resin (A2) has a weight average molecular weight of preferably 3,000 or more, more preferably 4,000 or more, still more preferably 5,000 or more, yet more preferably 6,000 or more, and preferably 100,000 or less, more preferably 50,000 or less, still more preferably 10,000 or less, yet more preferably 9,000 or less, further preferably 8,000 or less. Setting the weight average molecular weight within this range makes it possible to effectively prevent the film from being thinned and residues from remaining after development. The weight average molecular weight is determined as a value in terms of standard polystyrene by gel permeation chromatography analysis. Detailed analytical conditions of this analysis are described in examples of the present application.

The content of the resin (A2) is preferably 5 mass % or more, more preferably 10 mass % or more, still more preferably 20 mass % or more, and preferably 90 mass % or less, more preferably 80 mass % or less, still more preferably 70 mass % or less, yet more preferably 65 mass % or less based on the total amount of the resin included in the negative resist composition of the present invention.

### <Another Resin (A3)>

The negative resist composition of the present invention may contain a resin (hereinafter, may be referred to as “resin (A3)”) other than the resin (A1) and the resin (A2). Examples of the resin (A3) include a resin including the structural unit (a2-1) but not including the structural unit (a2-4), a resin including a structural unit derived from a (meth)acrylic acid ester, and a polyalkylene glycol.

<Resin Including Structural Unit Derived from (Meth)Acrylic Acid Ester>

Examples of the resin including a structural unit derived from a (meth)acrylic acid ester include a resin obtained by using the following compounds as monomers, combining one or more of the monomers, and polymerizing the monomers by a conventional method. Examples of the resin including a structural unit derived from a (meth)acrylic acid ester include a resin including a structural unit derived from a monomer as described below.

Monomers having a carboxyl group, such as (meth)acrylic acid; monomers having a hydroxyl group, such as 2-hydroxyethyl(meth)acrylate and 2-hydroxypropyl(meth)acrylate; and monomers having a plurality of ether bonds, such as polyethylene glycol monomethyl ether (meth)acrylates (polyalkylene glycol monoalkyl ether (meth)acrylates) including diethylene glycol monomethyl ether (meth)acrylate, triethylene glycol monomethyl ether (meth)acrylate, tetraethylene glycol monomethyl ether (meth)acrylate, pentaethylene glycol monomethyl ether (meth)acrylate, hexaethylene glycol monomethyl ether (meth)acrylate, heptaethylene glycol monomethyl ether (meth)acrylate, octaethylene glycol monomethyl ether (meth)acrylate, and nonaethylene glycol monomethyl ether (meth)acrylate.

The above-described monomers may also be used in combination of (meth)acrylic acid alkyl esters such as methyl (meth)acrylate, ethyl (meth)acrylate, propyl (meth)acrylate, tert-butyl (meth)acrylate, and hexyl (meth)acrylate; monocyclic (meth)acrylic acid esters such as (meth)acrylic acid cycloalkyl esters including cyclopentyl (meth)acrylate and cyclohexyl (meth)acrylate; polycyclic (meth)acrylic acid esters such as adamantyl (meth)acrylate and norbornyl (meth)acrylate; (meth)acrylic acid aryl esters such as phenyl (meth)acrylate and benzyl (meth)acrylate; or ethylene glycol monoalkyl ether (meth)acrylates (alkylene glycol monoalkyl ether (meth)acrylates) such as ethylene glycol monomethyl ether (meth)acrylate, ethylene glycol monoethyl ether (meth)acrylate, ethylene glycol monopropyl ether (meth)acrylate, and ethylene glycol monobutyl ether (meth)acrylate. In addition to the above monomers, styrenes such as styrene, α-methylstyrene, 4-methylstyrene, 2-methylstyrene, 3-methylstyrene, 4-methoxystyrene, and 4-isopropoxystyrene; carboxylic acids such as crotonic acid, maleic acid, fumaric acid, citraconic acid, mesaconic acid, and itaconic acid; and hydroxystyrenes exemplified above for resins including hydroxystyrene-derived structural units may also be used in combination. Examples of the structural unit derived from the monomer as described above also include structural units represented by the formulas (a2-1) to (a2-4).

### <Polyalkylene Glycol>

The polyalkylene glycol is a polymer obtained by addition polymerization of an alkylene oxide with an alcohol. Examples of the alcohols include butanol, ethylene glycol, propylene glycol, glycerin, and pentaerythritol. Examples of the alkylene oxide include ethylene oxide, propylene oxide, and butylene oxide. Examples of the polyalkylene glycol include polyethylene glycol, polypropylene glycol, and polybutylene glycol.

The content of the resin (A3) is preferably 3 mass % or more, more preferably 5 mass % or more, still more preferably 10 mass % or more, and preferably 50 mass % or less, more preferably 40 mass % or less, still more preferably 35 mass % or less, yet more preferably 30 mass % or less, based on the total amount of the resin included in the negative resist composition of the present invention.

### <Acid Generator (B)>

The acid generator (B) is a compound that can generate an acid by decomposition by light irradiation (exposure). The generated acid acts as an acid catalyst that promotes a crosslinking reaction, and the crosslinking agent and the reactive group in the resin can be bonded to form a crosslink. That is, exposing the negative resist composition including the resin (A) to light allows the negative resist composition to be made insoluble in a resist developer (alkali aqueous solution).

As the acid generator (B), either a non-ionic system or an ionic system may be used.

Examples of the nonionic acid generator include organic halides, sulfonate esters (for example, 2-nitrobenzyl ester, aromatic sulfonate, oxime sulfonate, N-sulfonyloxyimide, sulfonyloxyketone, and diazonaphthoquinone 4-sulfonate), and sulfones (for example, disulfone, ketosulfone, and sulfonyldiazomethane). As the ionic acid generator, for example, an onium salt including an onium cation (for example, a diazonium salt, a phosphonium salt, a sulfonium salt, and an iodonium salt) is representative. Examples of the anion of the onium salt include a sulfonate anion, a sulfonylimide anion, and a sulfonylmethide anion.

Specific examples of the acid generator (B) include compounds generating an acid upon exposure to radiation mentioned in JP-A-63-26653, JP-A-55-164824, JP-A-62-69263, JP-A-63-146038, JP-A-63-163452, JP-A-62-153853, JP-A-63-146029, U.S. Pat. Nos. 3,779,778, 3,849,137, DE Patent No. 3914407, and EP Patent No. 126,712. In addition, compounds produced by a known method may also be used. The acid generator (B) may be used singly or in combination of two or more thereof.

The nonionic acid generator is preferably a compound having a group represented by a formula (B1) (* represents a bond).

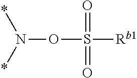

[In the formula (B1),
R^{b1} represents a hydrocarbon group having 1 to 18 carbon atoms and optionally having a fluorine atom, and the methylene group included in the hydrocarbon group having 1 to 18 carbon atoms may be substituted with an oxygen atom or a carbonyl group.]

The nitrogen atom may have a double bond.

Examples of the hydrocarbon group having 1 to 18 carbon atoms in the hydrocarbon group having 1 to 18 carbon atoms and optionally having a fluorine atom as for R^{b1} include a linear or branched chain hydrocarbon group having 1 to 18 carbon atoms, an alicyclic hydrocarbon group having 3 to 18 carbon atoms, an aromatic hydrocarbon group having 6 to 18 carbon atoms, and a group obtained by combining these groups and having 4 to 18 carbon atoms.

The linear or branched chain hydrocarbon group having 1 to 18 carbon atoms is preferably an alkyl group having 1 to 18 carbon atoms, and examples thereof include a methyl group, an ethyl group, a propyl group, a butyl group, a pentyl group, a hexyl group, a heptyl group, an octyl group, a nonyl group, and a decyl group. Among these, a linear one is preferable.

Examples of the alicyclic hydrocarbon group having 3 to 18 carbon atoms include a cyclopropyl group, a cyclobutyl group, a cyclopentyl group, a cyclohexyl group, a cycloheptyl group, a cyclooctyl group, and an adamantyl group.

The aromatic hydrocarbon group having 6 to 18 carbon atoms is preferably an aryl group having 6 to 18 carbon atoms, and examples thereof include aryl groups such as a phenyl group, a naphthyl group, an anthryl group, a biphenyl group, and a phenanthryl group.

Examples of the group obtained by combining a chain hydrocarbon group and an alicyclic hydrocarbon group (group having 4 to 18 carbon atoms) among the groups having 4 to 18 carbon atoms obtained by combining the above groups include a methylcyclohexyl group, a dimethylcyclohexyl group, a methylnorbornyl group, an isobornyl group, a 2-alkyladamantane-2-yl group, and a 1-(adamantane-1-yl)alkane-1-yl group.

Examples of the group in which a chain hydrocarbon group and an aromatic hydrocarbon group are combined (group having 7 to 18 carbon atoms) include an aralkyl group and an aromatic hydrocarbon group having an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Examples of the group in which an alicyclic hydrocarbon group and an aromatic hydrocarbon group are combined (group having 9 to 18 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group, a p-adamantylphenyl group, and a phenylcyclohexyl group.

Among the hydrocarbon groups having 1 to 18 carbon atoms and represented by R^{b1}, an alkyl group having 1 to 10 carbon atoms or an aromatic hydrocarbon group having 6 to 10 carbon atoms is preferable, an alkyl group having 1 to 8 carbon atoms is more preferable, and an alkyl group having 1 to 4 carbon atoms is still more preferable.

Examples of the group in which the methylene group included in the alicyclic hydrocarbon group having 3 to 18 carbon atoms in R^{b1} is substituted with an oxygen atom or a carbonyl group include groups represented by formulas (Y1) to (Y12). The group represented by the formula (Y7) to the formula (Y9) is preferable, and the group represented by the formula (Y9) is more preferable.

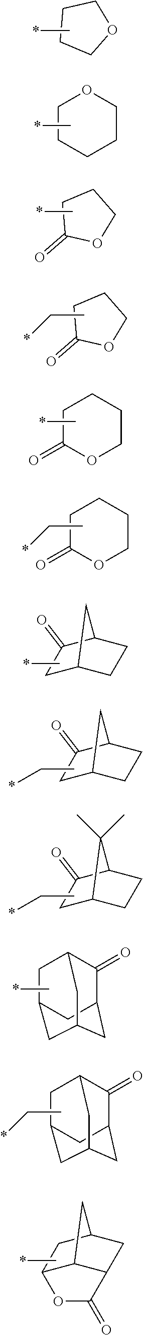

The hydrocarbon group having 1 to 18 carbon atoms and having a fluorine atom is a group in which one or more hydrogen atoms in the above hydrocarbon group having 1 to 18 carbon atoms are substituted with fluorine atoms, and specific examples include: fluoroalkyl groups such as a fluoromethyl group, a fluoroethyl group, a fluoropropyl group, a fluorobutyl group, a fluoropentyl group, a fluorohexyl group, a fluoroheptyl group, a fluorooctyl group, a fluorononyl group, and a fluorodecyl group; fluorocycloalkyl groups such as a fluorocyclopropyl group, a fluorocyclobutyl group, a fluorocyclopentyl group, a fluorocyclohexyl group, a fluorocycloheptyl group, a fluorocyclooctyl group, and a fluoroadamantyl group; and fluoroaryl groups such as a fluorophenyl group, a fluoronaphthyl group, and a fluoroanthryl group.

The hydrocarbon group having a fluorine atom and having 1 to 18 carbon atoms is preferably an alkyl group having a fluorine atom and having 1 to 10 carbon atoms or an aromatic hydrocarbon group having a fluorine atom and having 6 to 10 carbon atoms, more preferably a perfluoroalkyl group having 1 to 8 carbon atoms, and still more preferably a perfluoroalkyl group having 1 to 4 carbon atoms.

Examples of the compound having a group represented by the formula (B1) include compounds represented by a formula (b1) to a formula (b4). Compounds represented by the formulae (b1), (b2), and (b4) are preferable, and compounds represented by the formulae (b1) and (b4) are more preferable.

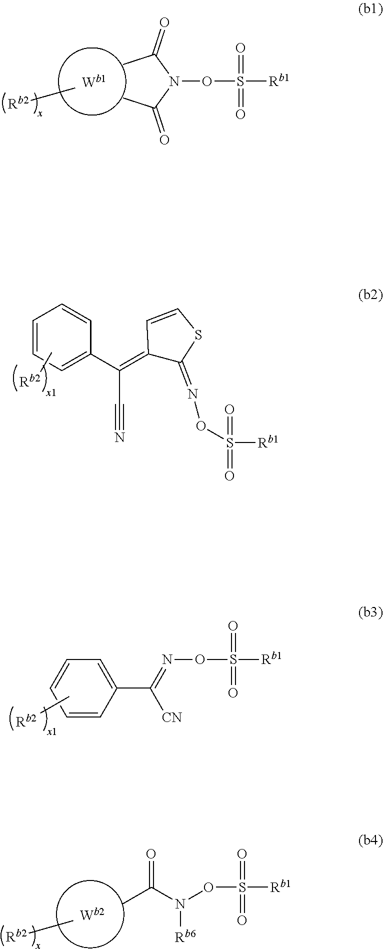

[In the formulas (b1) to (b4),
R^{b1} represents the same meaning as described above.
R^{b2} each independently represents an alkyl group having 1 to 8 carbon atoms or an alkoxy group having 1 to 8 carbon atoms.
A ring W^{b1} and a ring W^{b2} each independently represent an aromatic hydrocarbon ring having 6 to 14 carbon atoms or an aromatic heterocyclic ring having 6 to 14 carbon atoms.
x represents an integer of 0 to 6. When x is 2 or more, a plurality of R^{b2} may be the same or different.
x1 represents an integer of 0 to 5. When x1 is 2 or more, a plurality of R^{b2} may be the same or different.
R^{b6} represents a hydrogen atom or an alkyl group having 1 to 8 carbon atoms.]

Examples of the alkyl group having 1 to 8 carbon atoms include a methyl group, an ethyl group, a propyl group, a butyl group, and a pentyl group, and a methyl group is preferable.

Examples of the alkoxy group having 1 to 8 carbon atoms include a methoxy group, an ethoxy group, a propoxy group, a butoxy group, and a pentyloxy group, and the methoxy group is preferable.

Examples of the aromatic hydrocarbon ring having 6 to 14 carbon atoms include a benzene ring, a naphthalene ring, and an anthracene ring.

Examples of the aromatic heterocyclic ring having 6 to 14 carbon atoms include a ring having 6 to 14 atoms constituting the ring, and preferably include the following rings.

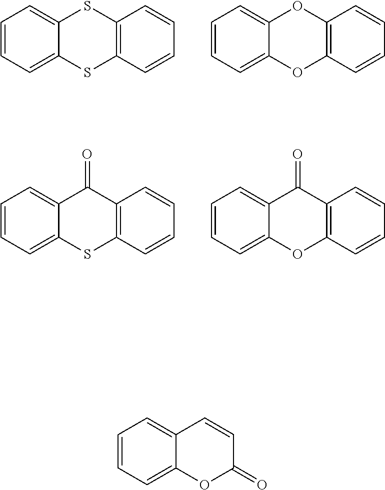

The ring W^{b1} and the ring W^{b2} are preferably naphthalene rings.

As the compound represented by the formula (b1), a compound represented by any one of the formula (b5) to the formula (b8) is preferable, and a compound represented by the formula (b5) is more preferable.

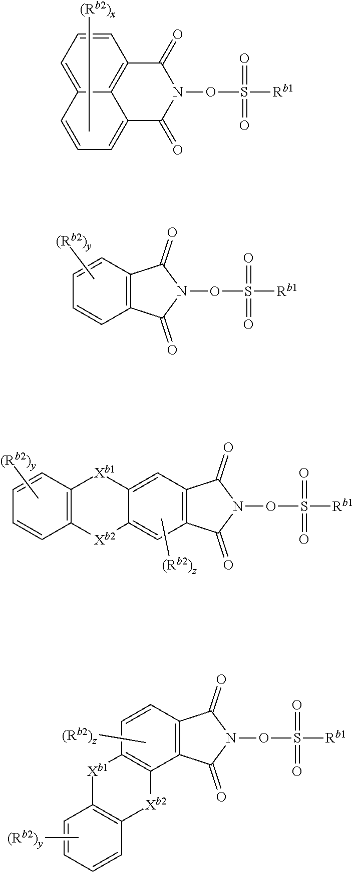

[In the formula (b5) to the formula (b8),
R^{b1}, R^{b2}, and x represent the same meaning as described above.
y represents an integer of 0 to 4. When y is 2 or more, a plurality of R^{b2} may be the same or different.
z represents an integer of 0 to 2. When z is 2, two R^{b2}s may be the same or different.
X^{b1} and X^{b2} each independently represent —O—, —S—, or —CO—.]

Examples of the compound represented by the formula (b1) include compounds represented by a formula (b1-1) to a formula (b1-17). Compounds represented by the formula (b1-6), the formula (b1-7), the formula (b1-10), the formula (b1-13), and the formula (b1-15) are preferable.

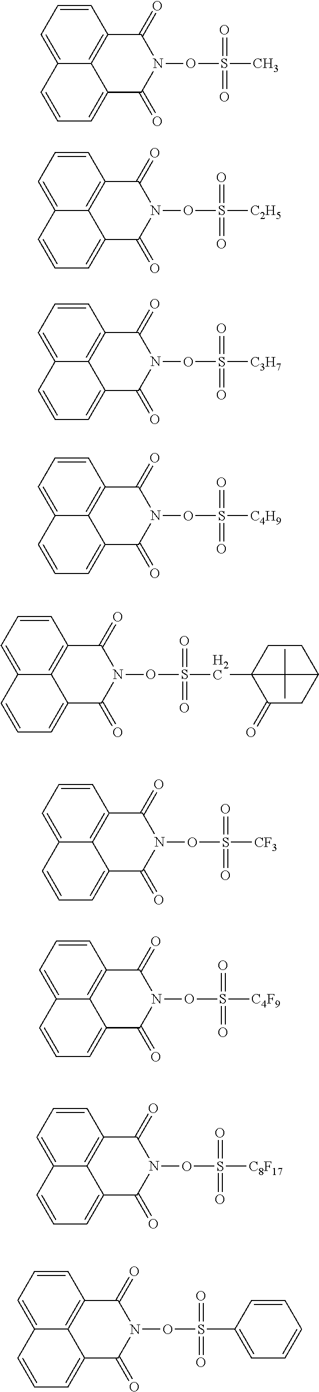

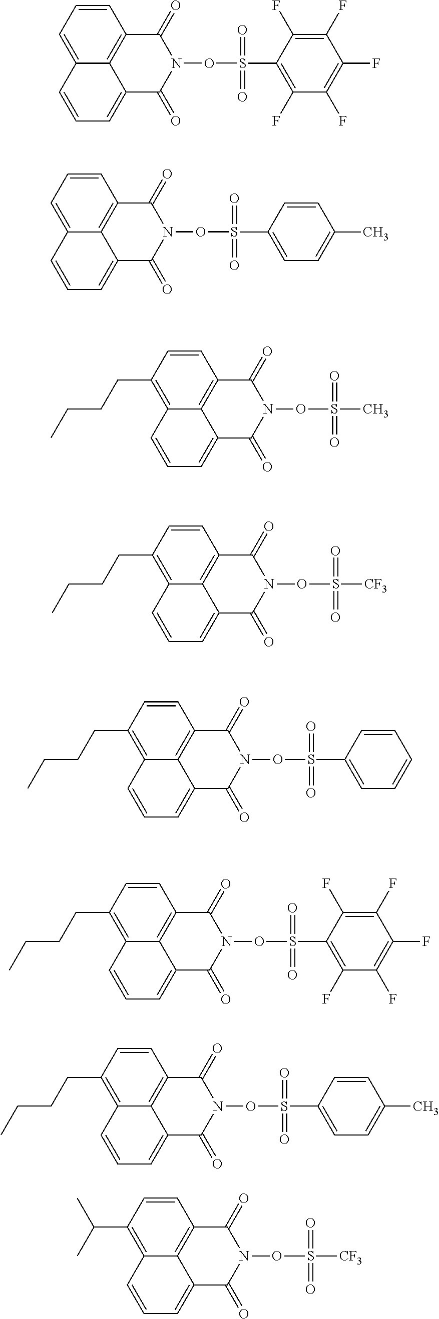

Examples of the compound represented by the formula (b2) include a compound represented by the following formula.

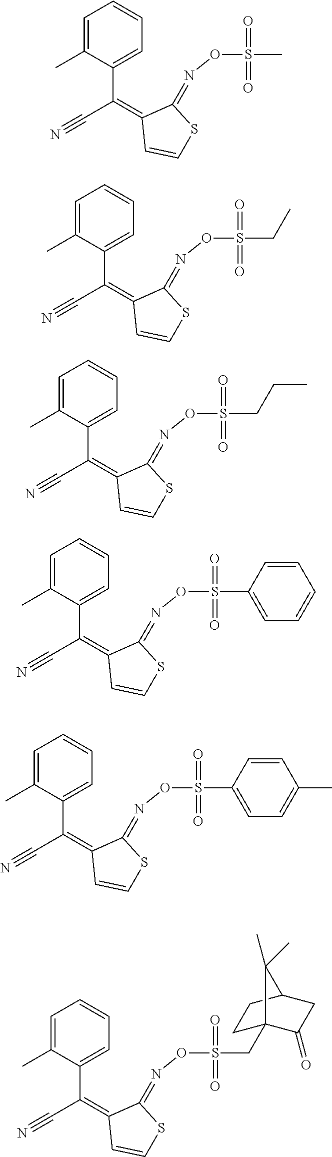

Examples of the compound represented by the formula (b3) include a compound represented by the following formula.

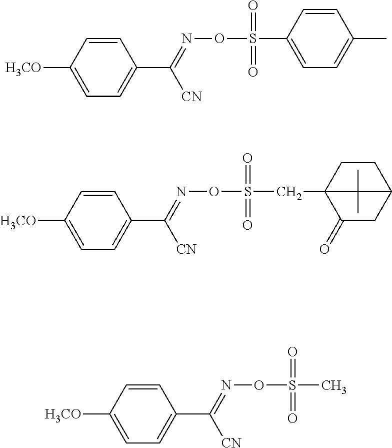 [SMILES: COc1ccc(/C(C#N)=N/OS(=O)(=O)c2ccc(C)cc2)cc1 ; COc1ccc(/C(C#N)=N/OS(=O)(=O)CC23CCC(CC2=O)C3(C)C)cc1 ; COc1ccc(/C(C#N)=N/OS(C)(=O)=O)cc1]

Examples of the compound represented by the formula (b4) include the compound represented by the following.

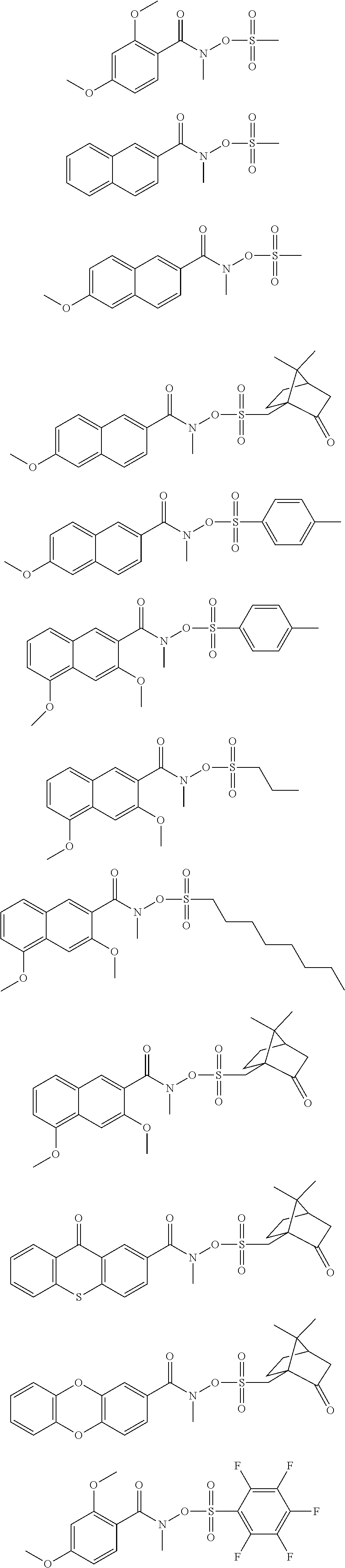

As the ionic acid generator, a compound represented by a formula (b9) or a formula (b10) is preferable.

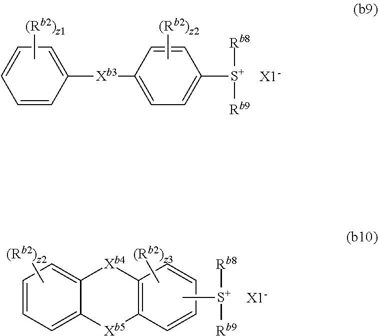

[In the formula (b9) and the formula (b10),
R^{b2} represents the same meaning as described above.
z1 represents an integer of 0 to 5. When z1 is 2 or more, a plurality of R^{b2} may be the same or different.
z2 represents an integer of 0 to 4. When z2 is 2 or more, a plurality of R^{b2} may be the same or different.
z3 represents an integer of 0 to 3. When z3 is 2 or more, a plurality of R^{b2} may be the same or different.
X^{b3} represents an oxygen atom or a sulfur atom.
X^{b4} and X^{b5} each independently represent an oxygen atom, a sulfur atom, or —CO—.
R^{b8} and R^{b9} each independently represent an alkyl group having 1 to 10 carbon atoms or an aromatic hydrocarbon group having 6 to 12 carbon atoms.
X1⁻ represents an organic anion.]

Examples of the alkyl group having 1 to 10 carbon atoms include a methyl group, an ethyl group, a propyl group, a butyl group, a pentyl group, a hexyl group, a heptyl group, and an octyl group.

Examples of the aromatic hydrocarbon group having 6 to 12 carbon atoms include aryl groups such as a phenyl group, a naphthyl group, an anthryl group, a biphenyl group, and a phenanthryl group. The aromatic hydrocarbon group may further have a substituent, and examples of the aromatic hydrocarbon group having a substituent include an aralkyl group and an aromatic hydrocarbon group having an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

R^{b8} and R^{b9} are each preferably an aromatic hydrocarbon group having 6 to 12 carbon atoms, and more preferably a phenyl group.

Examples of the organic anion represented by X1⁻ include a sulfonate anion, a bis(alkylsulfonyl)amide anion, and a tris(alkylsulfonyl)methide anion, and the organic anion is preferably a sulfonate anion, and more preferably a sulfonate anion represented by a formula (b11).

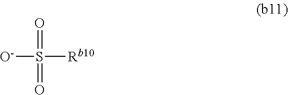

[In the formula (b11),
R^{b10} represents a hydrocarbon group having 1 to 18 carbon atoms and optionally having a fluorine atom, and the methylene group included in the hydrocarbon group may be substituted with an oxygen atom or a carbonyl group.]

Examples of R^{b10} include the same group as R^{b1} in the formula (B1).

Examples of the compound represented by the formula (b9) include the following compound.

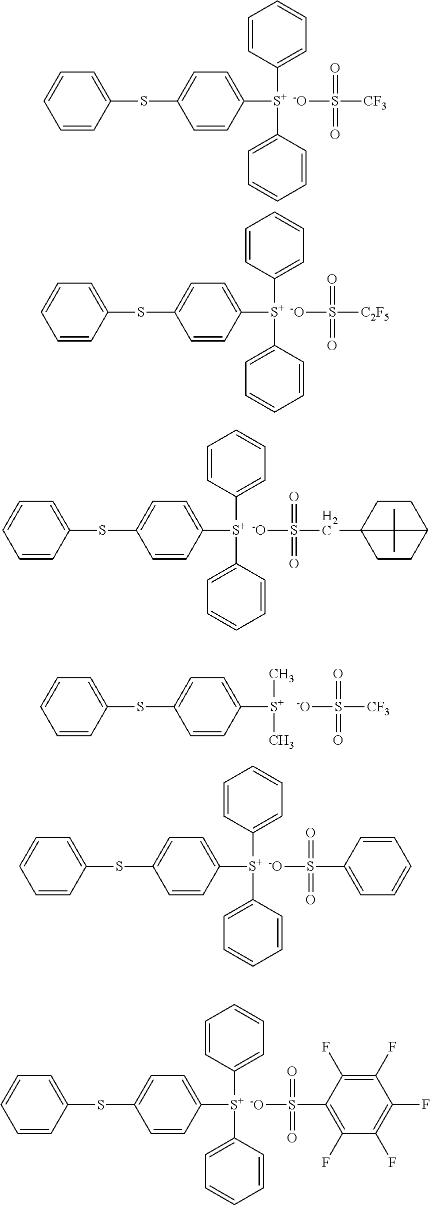

Examples of the compound represented by the formula (b10) include the following compound.

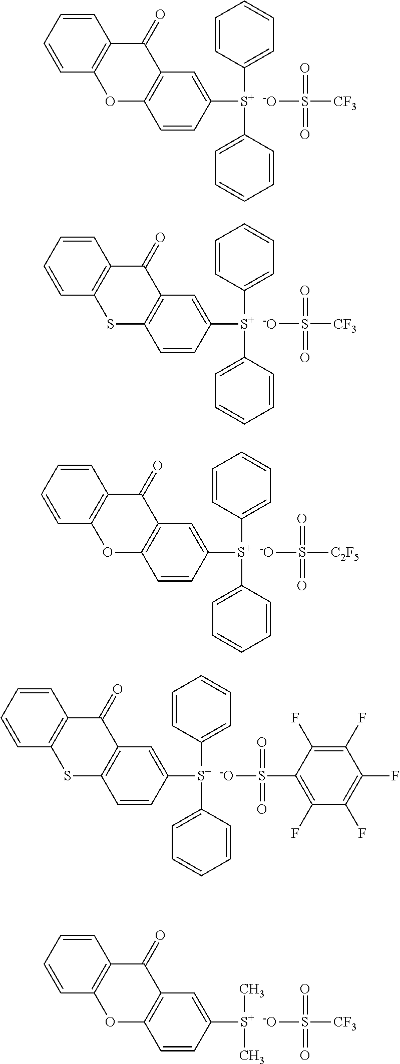

In the resist composition of the present invention, the content of the acid generator is preferably 0.1 parts by mass or more and 40 parts by mass or less, more preferably 0.5 parts by mass or more and 30 parts by mass or less, still more preferably 1 part by mass or more and 20 parts by mass or less, and yet more preferably 1 part by mass or more and 5 parts by mass or less, based on 100 parts by mass of the resin (A1). The resist composition of the present invention may contain a single type of the acid generator (B), or may contain two or more types thereof.

### <Crosslinking Agent (E)>

A crosslinking agent (E) is a compound that is bonded to the resin (A1) by the action of the acid generated from the acid generator (B) decomposed by light irradiation (exposure). Bonding to the resin forms a crosslinked structure.

Examples of the crosslinking agent include a melamine-based crosslinking agent, a urea-based crosslinking agent, an alkylene urea-based crosslinking agent, and a glycoluril-based crosslinking agent.

Examples of the melamine-based crosslinking agent include a compound represented by a formula (e1).

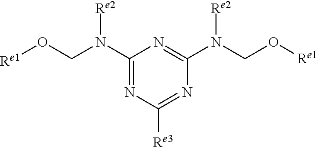

[In the formula (e1),
R^{e1} each independently represents a hydrogen atom or a hydrocarbon group having 1 to 6 carbon atoms.
R^{e2} each independently represents a hydrogen atom, a hydrocarbon group having 1 to 6 carbon atoms, or —CH₂—O—R^{e1}.
R^{e3} represents a hydrogen atom, a hydrocarbon group having 1 to 6 carbon atoms, or a group represented by a formula (e1-1).]

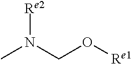

[In the formula (e1-1), R^{e1} and R^{e2} represent the same groups as in the formula (e1).]

Specific examples of the melamine-based crosslinking agent include N,N,N,N,N,N-hexakis(methoxymethyl)melamine, N,N,N,N,N,N-hexakis(ethoxymethyl)melamine, N,N,N,N,N,N-hexakis(propoxymethyl)melamine, N,N,N,N,N,N-hexakis(isopropoxymethyl)melamine, N,N,N,N,N,N-hexakis(butoxymethyl)melamine, N,N,N,N,N,N-hexakis(t-butoxymethyl)melamine, N,N,N,N,N,N-hexakis(cyclohexyloxymethyl)melamine, N,N,N,N,N,N-hexakis (cyclopentyloxymethyl)melamine, N,N,N,N,N,N-hexakis(adamantyloxymethyl)melamine,

N,N,N,N,N,N-hexakis (norbornyloxymethyl)melamine, N,N,N,N-tetrakis (methoxymethyl)acetoguanamine, N,N,N,N-tetrakis(ethoxymethyl)acetoguanamine, N,N,N,N-tetrakis(propoxymethyl)acetoguanamine, N,N,N,N-tetrakis(isopropoxymethyl)acetoguanamine, N,N,N,N-tetrakis(butoxymethyl)acetoguanamine, N,N,N,N-tetrakis(t-butoxymethyl) acetoguanamine, N,N,N,N-tetrakis(methoxymethyl)benzoguanamine, N,N,N,N-tetrakis(ethoxymethyl)benzoguanamine, N,N,N,N-tetrakis(propoxymethyl)benzoguanamine, N,N,N,N-tetrakis(isopropoxymethyl)benzoguanamine, N,N,N,N-tetrakis(butoxymethyl)benzoguanamine, and N,N,N,N-tetrakis(t-butoxymethyl)benzoguanamine.

Examples of the urea-based crosslinking agent include a compound represented by a formula (e2).

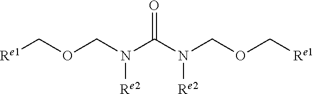

[In the formula (e2), R^{e} and R^{e2} represent the same groups as in the formula (e1).]

Specific examples of the urea-based crosslinking agent include N,N-di (methoxymethyl)urea, N,N-di (ethoxymethyl)urea, N,N-di (propoxymethyl)urea, N,N-di (isopropoxymethyl)urea, N,N-di (butoxymethyl)urea, N,N-di (t-butoxymethyl)urea, N,N-di (cyclohexyloxymethyl) urea, N,N-di (cyclopentyloxymethyl)urea, N,N-di (adamantyloxymethyl)urea, and N,N-di (norbornyloxymethyl)urea.

Examples of the alkylene urea-based crosslinking agent include a compound represented by a formula (e3).

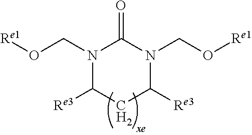

[In the formula (e3),
R^{e1} represents the same group as that of the formula (e1).
R^{e3} each independently represents a hydrogen atom, a hydroxyl group, a hydrocarbon group having 1 to 6 carbon atoms, or an alkoxy group having 1 to 6 carbon atoms. xe represents an integer of 0 to 2.]

Specific examples of the alkylene urea-based crosslinking agent include N,N-di(methoxymethyl)-4,5-di(methoxymethyl)ethyleneurea, N,N-di(ethoxymethyl)-4,5-di(ethoxymethyl)ethyleneurea, N,N-di(propoxymethyl)-4,5-di (propoxymethyl) ethyleneurea, N, N-di (isopropoxymethyl)-4,5-di(isopropoxymethyl)ethyleneurea, N,N-di(butoxymethyl)-4,5-di(butoxymethyl)ethyleneurea, N,N-di(t-butoxymethyl)-4,5-di(t-butoxymethyl)ethyleneurea, N,N-di(cyclohexyloxymethyl)-4,5-di(cyclohexyloxymethyl)ethyleneurea, N,N-di(cyclopentyloxymethyl)-4,5-di(cyclopentyloxymethyl)ethyleneurea,

N,N-di(adamantyloxymethyl)-4,5-di(adamantyloxymethyl)ethyleneurea, and N,N-di(norbornyloxymethyl)-4,5-di(norbornyloxymethyl)ethyleneurea.

Examples of the glycoluril-based crosslinking agent include a formula (e4).

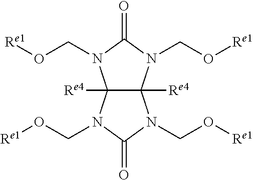

[In the formula (e4),
R^{e1} represents the same group as that of the formula (e1).
R^{e4} each independently represents a hydrogen atom, a hydroxyl group, a hydrocarbon group having 1 to 6 carbon atoms, or an alkoxy group having 1 to 6 carbon atoms.]

Specific examples of the glycoluril-based crosslinking agent include N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(t-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril, and N,N,N,N-tetra(norbornyloxymethyl)glycoluril.

Among the above, the crosslinking agent (E) is preferably a melamine-based crosslinking agent or a glycoluril-based crosslinking agent. The crosslinking agent (E) may be used singly, or two or more thereof may be used in combination.

In the negative resist composition of the present invention, the content of the crosslinking agent (E) is preferably 1 to 50 parts by mass, more preferably 2 to 40 parts by mass, and still more preferably 3 to 30 parts by mass, based on 100 parts by mass of the resin.

### <Aromatic Compound (I)>

The compound (I) is an aromatic compound having a molecular weight of 2,000 or less and having 3 or more phenolic hydroxyl groups in the molecule.

The compound (I) is preferably a compound having no molecular weight distribution, and the molecular weight of the compound (I) is not an average molecular weight.

The molecular weight of the compound (I) is, for example, 100 or more, preferably 120 or more, more preferably 150 or more, still more preferably 180 or more, and yet more preferably 200 or more. In addition, the molecular weight is, for example, 1,500 or less, preferably 1,200 or less, more preferably 1,000 or less, still more preferably 900 or less, yet more preferably 800 or less, further preferably 700 or less, and further more preferably 600 or less. Specifically, the molecular weight is, for example, 100 or more and 2,000 or less, preferably 100 or more and 1,500 or less, more preferably 100 or more and 1,200 or less, still more preferably 100 or more and 1,000 or less, yet more preferably 120 or more and 900 or less, further preferably 150 or more and 800 or less, further more preferably 180 or more and 700 or less, and still yet preferably 200 or more and 600 or less.

As described above, the compound (I) is preferably a low molecular weight compound, and the resin is excluded from the compound (I).

Examples of the compound (I) include the compound represented by the following formula (I0) (hereinafter, may be referred to as “compound (I0)”).

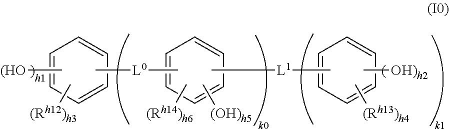

[In the formula (I0),
L⁰ and L¹ each independently represent a hydrocarbon group having 1 to 20 carbon atoms and optionally having a substituent, and a methylene group included in the hydrocarbon group may be substituted with an oxygen atom or a carbonyl group,
R^{h12}, R^{h13}, and R^{h14} each independently represent a halogen atom or a hydrocarbon group having 1 to 20 carbon atoms and optionally having a substituent, or R^{h12} and R^{h13}, R^{h12}, and R^{h14}, R^{h13} and R^{h14}, or R^{h12}, R^{h13}, or R^{h14} and L⁰ or L¹ may be bonded to form a ring optionally having a substituent,
k0 represents an integer of 0 to 6, when k0 is 2 or more, a plurality of groups in parentheses may be the same or different from each other,
k1 represents an integer of 1 to 6, when k1 is 2 or more, a plurality of groups in parentheses may be the same or different from each other,
h1 and h2 each independently represent an integer of 0 to 5,
h5 represents an integer of 0 to 4,
h3 and h4 each independently represent an integer of 0 to 5, when h3 or h4 is 2 or more, a plurality of R^{h12} or R^{h13} may be the same or different from each other, and h6 represents an integer of 0 to 4, when h6 is 2 or
more, a plurality of R^{h14} may be the same or different from each other,
provided that a sum of h1, h2, and h5 is 3 or more, a sum of h1 and h3 is 5 or less, a sum of h2 and h4 is 5 or less, and a sum of h5 and h6 is 4 or less.]

The compound (I0) is preferably, for example, a compound represented by the formula (I1) (hereinafter, may be referred to as “compound (I1)”).

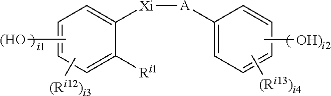

[In the formula (I1),
Xi represents a single bond or an oxygen atom,
A represents an alkanediyl group having 1 to 6 carbon atoms and optionally having a substituent, and a methylene group included in the alkanediyl group may be substituted with an oxygen atom or a carbonyl group, provided that when Xi is an oxygen atom, a methylene group bonded to Xi is not substituted with an oxygen atom,
i1 and i2 each independently represent an integer of 0 to 4, provided that a sum of i1 and i2 is 3 or more,
Rⁱ¹² and Rⁱ¹³ each independently represent a halogen atom or an alkyl group having 1 to 12 carbon atoms and optionally having a substituent,
i3 and i4 each independently represent an integer of 0 to 4, when i3 or i4 is 2 or more, a plurality of Rⁱ¹² or Rⁱ¹³ may be the same or different from each other, and
Rⁱ¹ represents a hydrogen atom or an alkyl group having 1 to 12 carbon atoms and optionally having a substituent, or when A is an alkanediyl group, Rⁱ¹ may be bonded to A to form a ring optionally having a substituent,
provided that a sum of i1 and i3 is 4 or less, and a sum of i2 and i4 is 5 or less.]

The compound (I1) is preferably a compound represented by a formula (Ia) or a formula (Ib) (hereinafter, may be referred to as “compound (Ia)” or “compound (Ib)”).

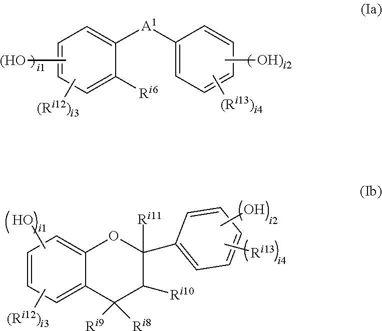

[In the formula (Ia) and the formula (Ib),
Rⁱ¹², Rⁱ¹³, and i1 to i4 have the same meaning as described above.
A1 represents a carbonyl group or an alkanediyl group having 1 to 6 carbon atoms.
Rⁱ⁶ represents a hydrogen atom or an alkyl group having 1 to 12 carbon atoms and optionally having a substituent.
Rⁱ⁸, Rⁱ⁹, Rⁱ¹⁰, and Rⁱ¹¹ each independently represent a hydrogen atom or an alkyl group having 1 to 12 carbon atoms, or Rⁱ⁸ and Rⁱ⁹ as well as Rⁱ¹⁰ and Rⁱ¹¹ may be bonded to each other to form a ring optionally having a substituent.]

The compound represented by the formula (Ib) is preferably a compound represented by a formula (Ib-1) (hereinafter, may be referred to as “compound (Ib-1)”).

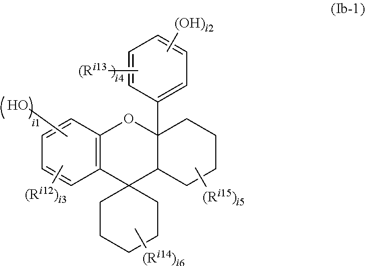

[In the formula (Ib-1),
Rⁱ¹², Rⁱ¹³, and i1 to i4 have the same meaning as described above.
Rⁱ¹⁴ and Rⁱ¹⁵ each independently represent an alkyl group having 1 to 12 carbon atoms, an alkenyl group having 1 to 12 carbon atoms, a cycloalkyl group having 3 to 12 carbon atoms, or an aryl group having 5 to 18 carbon atoms.
i5 represents an integer of 0 to 4. When i5 is 2 or more, a plurality of Rⁱ¹⁵ may be the same or different from each other.
i6 represents an integer of 0 to 5. When i6 is 2 or more, a plurality of Rⁱ¹⁴ may be the same or different from each other.]

In the formula (I0), examples of the halogen atom include a fluorine atom, an iodine atom, a chlorine atom, and a bromine atom.

Examples of the hydrocarbon group having 1 to 20 carbon atoms include a chain hydrocarbon group having 1 to 20 carbon atoms, an alicyclic hydrocarbon group having 3 to 20 carbon atoms, an aromatic hydrocarbon group having 6 to 20 carbon atoms, and a group having 4 to 20 carbon atoms and obtained by combining these groups. The chain hydrocarbon group may be linear or branched. The alicyclic hydrocarbon group and the aromatic hydrocarbon group may be either monocyclic or polycyclic.

Examples of the chain hydrocarbon groups having 1 to 20 carbon atoms include alkyl or alkanediyl groups having 1 to 20 carbon atoms, and examples thereof include: alkyl groups such as a methyl group, an ethyl group, a propyl group, a butyl group, a pentyl group, a hexyl group, a heptyl group, an octyl group, a nonyl group, and a decyl group; and alkanediyl groups such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group, an ethane-1,1-diyl group, a propane-1,1-diyl group, a propane-1,2-diyl group, a propane-2,2-diyl group, a pentane-2,4-diyl group, a 2-methylpropane-1,3-diyl group, a 2-methylpropane-1,2-diyl group,
a pentane-1,4-diyl group, and a 2-methylbutane-1,4-diyl group.

Examples of the alicyclic hydrocarbon groups having 3 to 20 carbon atoms include cycloalkyl groups or cycloalkanediyl groups having 3 to 20 carbon atoms, and examples thereof include: cycloalkyl groups such as a cyclopropyl group, a cyclobutyl group, a cyclopentyl group, a cyclohexyl group, a cycloheptyl group, a cyclooctyl group, a norbornyl group, and an adamantyl group; and cycloalkanediyl groups such as a cyclobutane-1,3-diyl group, a cyclopentane-1,3-diyl group, a cyclohexane-1,4-diyl group, a cyclooctane-1,5-diyl group, a norbornane-1,4-diyl group, a norbornane-2,5-diyl group, an adamantane-1,5-diyl group, and an adamantane-2,6-diyl group.

Examples of the aromatic hydrocarbon groups having 6 to 20 carbon atoms include aryl or arylene groups having 6 to 20 carbon atoms, and examples thereof include: aryl groups such as a phenyl group, a naphthyl group, an anthryl group, a biphenyl group, and a phenanthryl group; and arylene groups such as a phenylene group, a naphthylene group, an anthrylene group, a biphenylene group, and a phenanthrylene group.

Examples of the group obtained by combining a chain hydrocarbon group and an alicyclic hydrocarbon group (group having 4 to 20 carbon atoms) among the groups having 4 to 20 carbon atoms obtained by combining the above groups include a methylcyclohexyl group, a dimethylcyclohexyl group, a methylnorbornyl group, an isobornyl group, a 2-alkyladamantane-2-yl group, and a 1-(adamantane-1-yl)alkane-1-yl group.

Examples of the group in which a chain hydrocarbon group and an aromatic hydrocarbon group are combined (group having 7 to 20 carbon atoms) include an aralkyl group and an aromatic hydrocarbon group having an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Examples of the group in which an alicyclic hydrocarbon group and an aromatic hydrocarbon group are combined (group having 9 to 20 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group, a p-adamantylphenyl group, and a phenylcyclohexyl group.

Examples of the substituent include a halogen atom, an alkyl group having 1 to 12 carbon atoms, an alkenyl group having 1 to 12 carbon atoms, a cycloalkyl group having 3 to 12 carbon atoms, and an aryl group having 5 to 18 carbon atoms.

In the formula (I1) and subsequent formulas, the alkanediyl group having 1 to 6 carbon atoms may be either linear or branched, and examples thereof include a methylene group, an ethylene group, a propane-1,3-diyl group, a butane-1,4-diyl group, a pentane-1,5-diyl group, a hexane-1,6-diyl group, an ethane-1,1-diyl group, a propane-1,1-diyl group, a propane-1,2-diyl group, a propane-2,2-diyl group, a pentane-2,4-diyl group, a 2-methylpropane-1,3-diyl group, a 2-methylpropane-1,2-diyl group, a pentane-1,4-diyl group, and a 2-methylbutane-1,4-diyl group.

Examples of the halogen atom include a fluorine atom, an iodine atom, a chlorine atom, and a bromine atom.

Examples of the alkyl group having 1 to 12 carbon atoms include a methyl group, an ethyl group, a propyl group, an isopropyl group, a butyl group, a pentyl group, and a hexyl group.

Examples of the alkenyl group having 1 to 12 carbon atoms include a vinyl group, an allyl group, a butenyl group, a pentenyl group, and a hexenyl group.

The cycloalkyl group having 3 to 12 carbon atoms may be either monocyclic or polycyclic, and examples thereof include a cyclopropyl group, a cyclobutyl group, a cyclopentyl group, a cyclohexyl group, a cyclononyl group, and a cyclododecyl group.

Examples of the aryl group having 5 to 18 carbon atoms include a phenyl group, a naphthyl group, an anthryl group, a biphenyl group, and a phenanthryl group.

R^{h12}, R^{h13}, or R^{h14} of the formula (I0) and L⁰ or L¹, Rⁱ¹ and A of the formula (I1), and the like may be bonded to each other to form a ring. The total number of carbon atoms in such a ring is preferably 3 to 24, and more preferably 3 to 20. Examples of such a ring include the following groups. The following groups are not described, but may have other groups. * represents a bond.

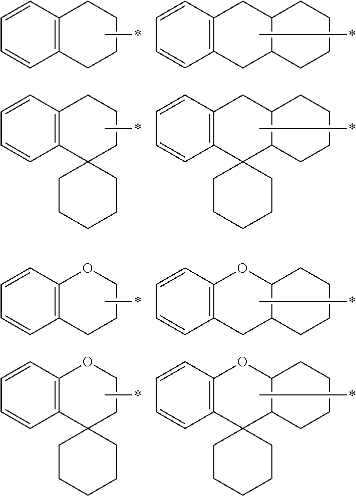

A1 is preferably a carbonyl group or a methylene group.

The sum of i1 and i2 is preferably 3 to 6, more preferably 3 to 5, and still more preferably 3 or 4.

Rⁱ¹² and Rⁱ¹³ are each independently preferably a halogen atom or an alkyl group having 1 to 4 carbon atoms, and preferably a fluorine atom, a methyl group, or an ethyl group.
Rⁱ⁸, Rⁱ⁹, Rⁱ¹⁰, and Rⁱ¹¹ are each independently preferably a hydrogen atom, an alkyl group having 1 to 4 carbon atoms, or a ring formed by bonding together and optionally having a substituent, more preferably a hydrogen atom, a methyl group, or a ring formed by bonding together and optionally having a substituent, and still more preferably a methyl group or a ring formed by bonding together and optionally having a substituent.

In the formula (Ia), i3 and i4 are each independently preferably 0 to 2.

In the formula (Ib) and the formula (Ib-1), i3 to i5 are each independently preferably 0 or 1, and more preferably 0. i6 is preferably 0.

Examples of the compound (I) include the following compounds.

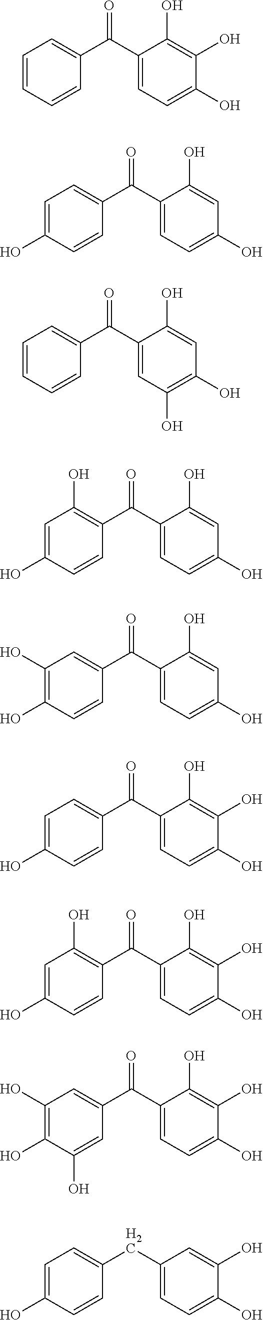

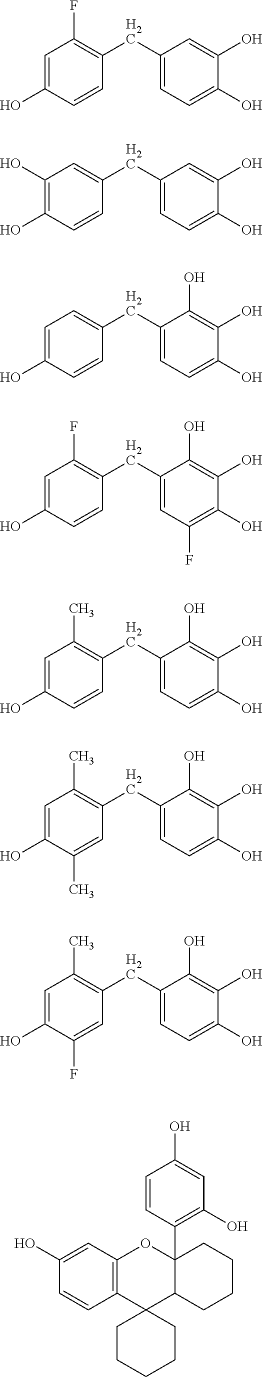

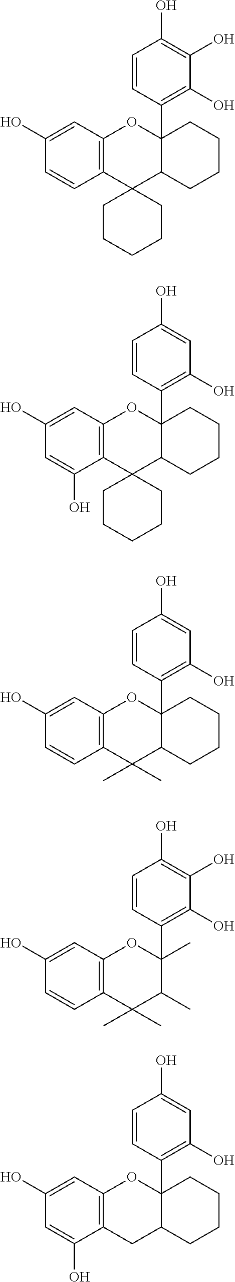

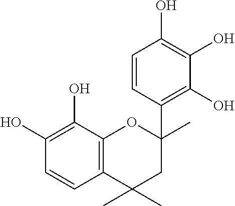 [SMILES: CC1(C)CC(C)(c2ccc(O)c(O)c2O)Oc2c1ccc(O)c2O]

As the compound (I), for example, compounds described in JP-A-3-191351, JP-A-8-99922, JP-A-9-292714, and JP-A-2001-100406 can be used. In addition, the compound (I) can be synthesized by a known method, and a compound produced by a known method may be used, or a commercially available product may be used.

The compound (I) may be used singly, or two or more thereof may be used in combination.

In the negative resist composition of the present invention, the content of the compound (I) is preferably 0.5 to 20 parts by mass, more preferably 1 to 15 parts by mass, and still more preferably 2 to 10 parts by mass, based on 100 parts by mass of the resin.

### <Solvent (D)>

The content of the solvent (D) is typically 40 mass % or more, preferably 45 mass % or more, more preferably 50 mass % or more, and typically 99.9 mass % or less, preferably 99 mass % or less, more preferably 90 mass % or less in the negative resist composition. The content of the solvent (D) can be measured, for example, by a known analysis means such as liquid chromatography or gas chromatography.

Examples of the solvent (D) include glycol ether esters such as ethylcellosolve acetate, methylcellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as γ-butyrolactone.

The solvent (D) may be included singly, or two or more thereof may be included.

### <Quencher (C)>

The negative resist composition of the present invention may contain a quencher (hereinafter, may be referred to as a “quencher (C)”).

The quencher (C) is a compound having an action of capturing an acid generated from an acid generator upon exposure to light. Examples of the quencher (C) include basic nitrogen-containing organic compounds. Examples of the basic nitrogen-containing organic compound include amine and an ammonium salt. Examples of the amine include aliphatic amines (including a primary amine, a secondary amine, and a tertiary amine) and aromatic amines.

Examples of the amine include a compound represented by a formula (C1) or a formula (C2).

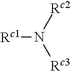

[In the formula (C1), R^{c1}, R^{c2}, and R^{c3} each independently represent a hydrogen atom, an alkyl group having 1 to 6 carbon atoms, an alicyclic hydrocarbon group having 3 to 10 carbon atoms, or an aromatic hydrocarbon group having 6 to 10 carbon atoms, and the alkyl group having 1 to 6 carbon atoms and the alicyclic hydrocarbon group having 3 to 10 carbon atoms may have at least one selected from the group consisting of a hydroxy group, an amino group, and an alkoxy group having 1 to 6 carbon atoms, and the aromatic hydrocarbon group having 6 to 10 carbon atoms may have at least one selected from the group consisting of an alkyl group having 1 to 6 carbon atoms, an alkoxy group having 1 to 6 carbon atoms, and an alicyclic hydrocarbon group having 3 to 10 carbon atoms.]

Examples of the alkyl group having 1 to 6 carbon atoms, the alicyclic hydrocarbon group having 3 to 10 carbon atoms, the aromatic hydrocarbon group having 6 to 10 carbon atoms, and the alkoxy group having 1 to 6 carbon atoms in the formula (C1) include the same groups as those described above.

Examples of the compounds represented by the formula (C1) include 1-naphthylamine, 2-naphthylamine, aniline, diisopropylaniline, 2-, 3-, or 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, dibutylmethylamine, methyldipentylamine, dihexylmethylamine, dicyclohexylmethylamine, diheptylmethylamine, methyldioctylamine, methyldinonylamine, didecylmethylamine,

ethyldibutylamine, ethyldipentylamine, ethyldihexylamine, ethyldiheptylamine, ethyldioctylamine, ethyldinonylamine, ethyldidecylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane, and 4,4′-diamino-3,3′-diethyldiphenylmethane. Preferable is diisopropylaniline, and particularly preferable is 2,6-diisopropylaniline.

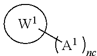

[In the formula (C2),
The ring W¹ represents a heterocyclic ring including a nitrogen atom in an atom constituting the ring or a benzene ring having a substituted or unsubstituted amino group, and the heterocyclic ring and the benzene ring may have at least one selected from the group consisting of a hydroxy group and an alkyl group having 1 to 4 carbon atoms.
A¹ represents a phenyl group or a naphthyl group.
nc represents 2 or 3, and a plurality of A1 may be the same or different.]

The substituted or unsubstituted amino group is represented by —N(R⁴) (R⁵), and R⁴ and R⁵ each independently represent a hydrogen atom, a chain hydrocarbon group having 1 to 10 carbon atoms, an alicyclic hydrocarbon group having 3 to 10 carbon atoms, or an aromatic hydrocarbon group having 6 to 14 carbon atoms.

Examples of the chain hydrocarbon group having 1 to 10 carbon atoms include alkyl groups having 1 to 10 carbon atoms such as a methyl group, an ethyl group, a propyl group, a butyl group, a pentyl group, a hexyl group, a heptyl group, and an octyl group.

Examples of the alicyclic hydrocarbon group having 3 to 10 carbon atoms include: monocyclic alicyclic hydrocarbon groups such as cycloalkyl groups including a cyclopentyl group, a cyclohexyl group, a cycloheptyl group, and a cyclooctyl group; and polycyclic alicyclic hydrocarbon groups such as a decahydronaphthyl group, an adamantyl group, and a norbornyl group.

Examples of the aromatic hydrocarbon group having 6 to 14 carbon atoms include aryl groups such as a phenyl group, a naphthyl group, an anthryl group, a biphenyl group, and a phenanthryl group. The aromatic hydrocarbon group may further have a substituent, and examples of the substituent include an aryloxy group having 6 to 10 carbon atoms.

The heterocyclic ring including a nitrogen atom as an atom constituting the ring may be an aromatic ring or a non-aromatic ring, and may have another heteroatom (for example, an oxygen atom or a sulfur atom) together with the nitrogen atom. The number of nitrogen atoms included in the heterocyclic ring is, for example, 1 to 3. Examples of the heterocyclic ring include the rings represented by any of formulas (Y13) to (Y28). One of the hydrogen atoms included in the ring is taken to form a bond with A¹.

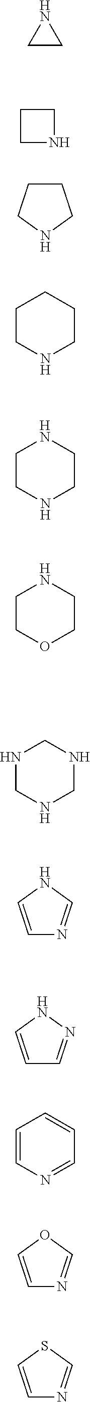

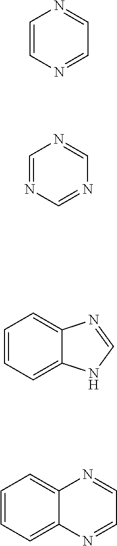 [SMILES: c1cnccn1 ; c1ncncn1 ; c1ccc2[nH]cnc2c1 ; c1ccc2nccnc2c1]

The ring W¹ is preferably a heterocyclic ring including a nitrogen atom in an atom constituting the ring, more preferably a 5- or 6-membered aromatic heterocyclic ring including a nitrogen atom in an atom constituting the ring, and still more preferably a ring represented by any one of the formulas (Y20) to (Y25).

Examples of the compound represented by the formula (C2) include compounds represented by any of the formulas (C2-1) to (C2-11). The compound is preferably a compound represented by any one of a formula (C2-2) to a formula (C2-8).

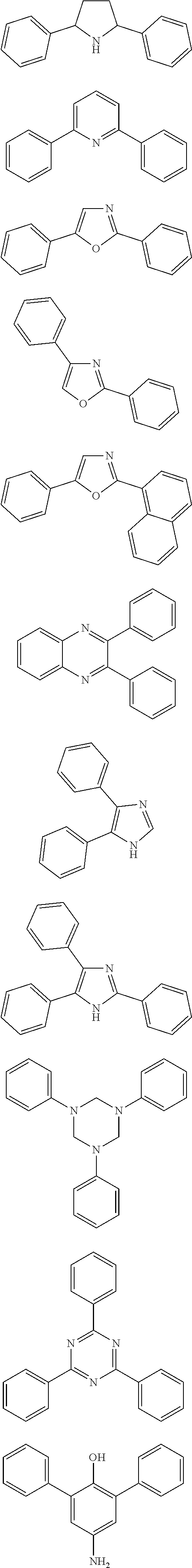

The content of the quencher (C) is preferably 0.0001 to 5 mass %, more preferably 0.0001 to 4 mass %, still more preferably 0.001 to 3 mass %, yet more preferably 0.01 to 1.0 mass %, and further preferably 0.1 to 0.7 mass % in the solid content of the negative resist composition.

### <Other Components (F)>

The negative resist composition of the present invention may also include components other than the components mentioned above (hereinafter sometimes referred to as “other components (F)”). The other components (F) are not particularly limited, and additives known in the resist field, for example, a sensitizer, a dissolution inhibitor, a surfactant, a stabilizer, a dye, an adhesion improver, and the like can be used.

When the other components (F) are used, the content thereof is appropriately selected according to the type of the other components (F).

### 2. Preparation of Negative Resist Composition

The negative resist composition of the present invention can be prepared by mixing the resin (A1), the acid generator (B), the crosslinking agent (E), and the aromatic compound (I), and as necessary, a resin other than the resin (A1), the quencher (C), the solvent (D), and other components (F). The order of mixing these components is any order and is not particularly limited. Examples of the temperature during mixing include 10 to 40° C., and an appropriate temperature can be selected according to the type of the resin or the like, the solubility of the resin or the like in the solvent (D), and the like. It is possible to select, as the mixing time, appropriate time from 0.5 to 24 hours according to the mixing temperature. The mixing means is not particularly limited and it is possible to use mixing with stirring.

After mixing the respective components, the mixture is preferably filtered through a filter having a pore diameter of about 0.003 to 50 μm.

### 3. Method for Producing Resist Pattern

The method for producing a resist pattern of the present invention includes:
(1) applying the negative resist composition of the present invention onto a substrate;
(2) drying the applied negative resist composition to form a composition layer;
(3) exposing the composition layer; and
(4) heating and developing the exposed composition layer.

The negative resist composition can be usually applied on a substrate using a conventionally used apparatus, such as a spin coater. Examples of the substrate include an inorganic substrate such as a silicon wafer, and a semiconductor element (for example, a transistor and a diode) or the like may be previously formed on the substrate.

The solvent is removed by drying the applied composition to form a composition layer. Drying is performed by evaporating the solvent using a heating device such as a hot plate (so-called “prebake”), or a decompression device. The heating temperature is preferably 50 to 200° C. and the heating time is preferably 30 to 600 seconds. The pressure during drying under reduced pressure is preferably about 1 to 1.0×10⁵ Pa.

After drying, the film thickness of the obtained composition is preferably 10 nm to 3 μm, and more preferably 100 nm to 1 μm.

The composition layer thus obtained is typically exposed using an aligner. As the exposure light source, various light sources can be used, such as a light source that emits light having a wavelength of 345 to 436 nm (g ray (wavelength: 436 nm), h ray (wavelength: 405 nm), i ray (wavelength: 365 nm)), a light source that emits laser light in the ultraviolet range such as a KrF excimer laser (wavelength 248 nm), an ArF excimer laser (wavelength 193 nm), or an F₂ excimer laser (wavelength 157 nm), a light source that converts the wavelength of laser light from a solid-state laser light source (YAG, semiconductor laser, or the like) to emit harmonic laser light in the far ultraviolet range or the vacuum ultraviolet range, an electron beam, and a light source that emits ultra (extreme) ultraviolet light (EUV). Among these, the i-line is preferably used as an exposure light source.

As used herein, such exposure to radiation may be collectively referred to as “exposure”. The exposure is typically performed through a mask corresponding to a pattern to be required. When electron beam is used as the exposure light source, exposure may be performed by direct writing without using the mask.

A heat treatment (so-called post-exposure baking) may be added to the exposed composition layer in order to promote the crosslinking reaction between the resin and the crosslinking agent. The heating temperature is usually about 50 to 200° C., and preferably about 70 to 150° C. The heating time is typically 40 to 400 seconds, preferably 50 to 350 seconds.

The heated composition layer is typically developed with a developing solution using a development apparatus. Examples of the developing method include a dipping method, a paddle method, a spraying method, and a dynamic dispensing method. The developing temperature is preferably, for example, 5 to 60° C. and the developing time is preferably, for example, 5 to 600 seconds.

The negative resist composition of the present invention uses an alkaline developer as a developer. The alkaline developer may be various aqueous alkaline solutions used in this field. Examples thereof include aqueous solutions of tetramethylammonium hydroxide and (2-hydroxyethyl)trimethylammonium hydroxide (commonly known as choline). The surfactant may be included in the alkaline developer.

It is preferable that the developed resist pattern is washed with ultrapure water and then water remaining on the substrate and the pattern is removed.

After washing, the rinsing solution remaining on the substrate and the pattern is preferably removed.

A resist pattern having a highly accurate shape can be formed by exposing a resist obtained using the negative resist composition of the present invention.

### 4. Application

The negative resist composition of the present invention is useful, for example, for producing a resist film having a film thickness of 1 μm or less.

### EXAMPLES

The present invention will be described more specifically by way of Examples. Percentages and parts expressing the contents or amounts used in the Examples are by mass unless otherwise specified.

The weight-average molecular weight is a value obtained by gel permeation chromatography under the following conditions.

Apparatus: HLC-8320GPC type (manufactured by Tosoh Corporation)

Column: TSKgel Multipore HXL-M×3+guardcolumn (manufactured by Tosoh Corporation)

Eluent: tetrahydrofuran

Flow rate: 1.0 mL/min

Detector: RI detector

Column temperature: 40° C.

Injection amount: 100 μl

Molecular weight standards: polystyrene standard (manufactured by Tosoh Corporation)

### <Preparation of Negative Resist Composition>

The mixture obtained by mixing and dissolving the components shown in Table 1 was filtered through a fluororesin filter having a pore size of 0.5 μm to prepare a negative resist composition.

TABLE 1

| | Negative | | Acid | Crosslinking | | | |
|---|---|---|---|---|---|---|---|
| | resist | Resin | generator | agent | Quencher | Compound | Solvent |
| | composition | (A1) | (B) | (E) | (C) | (I) | (D) |
| Example 1 | Composition | (A1)-1 = | (B1)-1 = | (E)-1 = | (C)-1 = | (I)-1 = | (D)-1 = |
| | 1 | 13.5 parts | 0.15 parts | 1.25 parts | 0.04 parts | 0.80 parts | 120 parts |
| | | | (B2)-1 = | | | | |
| | | | 0.10 parts | | | | |
| Example 2 | Composition | (A1)-1 = | (B1)-1 = | (E)-1 = | (C)-1 = | (I)-1 = | (D)-1 = |
| | 2 | 4.5 parts | 0.15 parts | 1.25 parts | 0.04 parts | 0.80 parts | 120 parts |
| | | (A1)-2 = | (B2)-1 = | | | | |
| | | 9.0 parts | 0.10 parts | | | | |
| Example 3 | Composition | (A1)-2 = | (B1)-1 = | (E)-1 = | (C)-1 = | (I)-1 = | (D)-1 = |
| | 3 | 13.5 parts | 0.15 parts | 1.25 parts | 0.04 parts | 0.80 parts | 120 parts |
| | | | (B2)-1 = | | | | |
| | | | 0.10 parts | | | | |
| Example 4 | Composition | (A1)-2 = | (B1)-1 = | (E)-1 = | (C)-1 = | (I)-1 = | (D)-1 = |
| | 4 | 13.5 parts | 0.15 parts | 1.25 parts | 0.04 parts | 1.12 parts | 120 parts |
| | | | (B2)-1 = | | | | |
| | | | 0.10 parts | | | | |
| Example 5 | Composition | (A1)-2 = | (B1)-1 = | (E)-1 = | (C)-1 = | (I)-1 = | (D)-1 = |
| | 5 | 13.5 parts | 0.20 parts | 1.25 parts | 0.04 parts | 1.12 parts | 120 parts |
| | | | (B2)-1 = | | | | |
| | | | 0.12 parts | | | | |
| Example 6 | Composition | (A1)-2 = | (B1)-1 = | (E)-1 = | (C)-1 = | (I)-1 = | (D)-1 = |
| | 6 | 13.5 parts | 0.15 parts | 1.25 parts | 0.04 parts | 1.12 parts | 120 parts |
| | | | (B2)-1 = | | | | |
| | | | 0.12 parts | | | | |
| Example 7 | Composition | (A1)-3 = | (B1)-1 = | (E)-1 = | (C)-1 = | (I)-1 = | (D)-1 = |
| | 7 | 13.5 parts | 0.15 parts | 1.25 parts | 0.04 parts | 0.80 parts | 120 parts |
| | | | (B2)-1 = | | | | |
| | | | 0.12 parts | | | | |
| Example 8 | Composition | (A1)-3 = | (B1)-1 = | (E)-1 = | (C)-1 = | (I)-1 = | (D)-1 |
| | 8 | 13.5 parts | 0.15 parts | 1.25 parts | 0.04 parts | 0.80 parts | 120 parts |
| | | | (B2)-1 = | | | (I)-2 = | |
| | | | 0.10 parts | | | 0.80 parts | |
| Comparative | Comparative | (A1)-2 = | (B1)-1 = | (E)-1 = | (C)-1 = | — | (D)-1 = |
| Example 1 | Composition | 13.5 parts | 0.15 parts | 1.25 parts | 0.04 parts | | 120 parts |
| | 1 | | (B2)-1 = | | | | |
| | | | 0.10 parts | | | | |
| Comparative | Comparative | (A1)-1 = | (B1)-1 = | (E)-1 = | (C)-1 = | (IX)-1 = | (D)-1 = |
| Example 2 | Composition | 13.5 parts | 0.15 parts | 1.25 parts | 0.04 parts | 0.8 parts | 120 parts |
| | 2 | | (B2)-1 = | | | | |
| | | | 0.10 parts | | | | |

### <Resin>

### (A1)-1: Resin (A1)-1

A resin including the following constituent units. Synthesis was performed by the method described in JP-A-2001-42529.

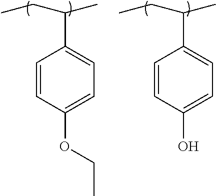

Weight-average molecular weight: 3700

The ratio of substitution of an ethoxy group for a hydroxy group in poly-p-hydroxystyrene was 20.9%.

### (A1)-2: Resin (A1)-2

A resin including the following constituent units. Synthesis was performed by the method described in JP-A-2001-42529.

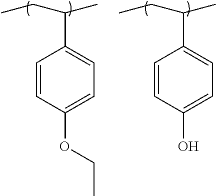

Weight-average molecular weight: 3700

The ratio of substitution of an ethoxy group for a hydroxy group in poly-p-hydroxystyrene was 27.0%.

### (A1)-3: Resin (A1)-3

A resin including the following constituent units. Synthesis was performed by the method described in JP-A-2001-42529.

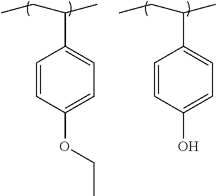

Weight-average molecular weight: 2800

The ratio of substitution of an ethoxy group for a hydroxy group in poly-p-hydroxystyrene was 21.0%.

### <Acid Generator (B)>

(B1)-1: Compound represented by the following formula (synthesized by the method described in WO 2014/084269)

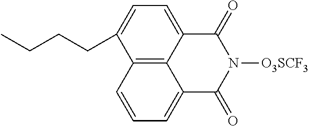

(B2)-1: Compound represented by the following formula (manufactured by BASF)

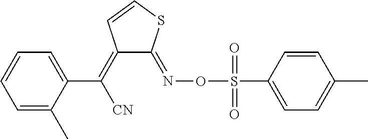 [SMILES: Cc1ccc(S(=O)(=O)O/N=C2\SC=C\C2=C(\C#N)c2ccccc2C)cc1]

### <Crosslinking Agent (E)>

(E)-1: Compound represented by the following formula (manufactured by Heraeus Holding GmbH)

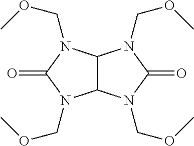

### <Quencher (C)>

(C)-1: 2,4,5-triphenylimidazole (manufactured by Tokyo Chemical Industry Co., Ltd.)

### <Compound (I)>

(I)-1: Compound represented by the following formula (manufactured by Tokyo Chemical Industry Co., Ltd.), molecular weight: 246

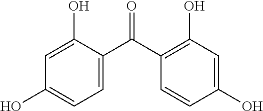 [SMILES: O=C(c1ccc(O)cc1O)c1ccc(O)cc1O]

(I)-2: Compound represented by the following formula (molecular weight: 380)

Synthesized with reference to JP-A-3-185447

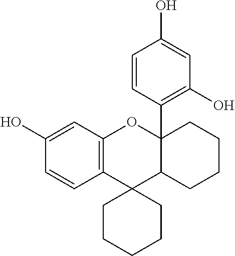 [SMILES: Oc1ccc(C23CCCCC2C2(CCCCC2)c2ccc(O)cc2O3)c(O)c1]

(IX)-1: Compound represented by the following formula (manufactured by Tokyo Chemical Industry Co., Ltd.), molecular weight: 273

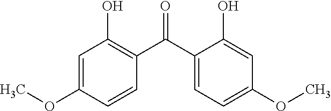

### <Solvent (D)>

(D)-1: Propylene glycol monomethyl ether acetate

### Examples 1 to 8 and Comparative Examples 1 and 2

(i-Ray Exposure Evaluation of Negative Resist Composition)

The negative resist composition was spin-coated on a 4 inch hexamethyldisilazane (HMDS)-treated silicon wafer substrate such that the film thickness after prebaking was 550 nm.

Thereafter, prebaking was performed at 110° C. for 60 seconds on a direct hot plate to form a composition layer.

Then, the composition layer formed on the wafer was exposed through a mask to form a 1:1 line-and-space pattern (line width: 800 nm, 700 nm, 600 nm, 500 nm) with stepwise varying exposure dose using an i-line stepper (NSR-2005i9C; manufactured by Nikon Corporation, NA=0.5).

After exposure, post-exposure baking was performed on the hot plate at 110° C. for 60 seconds, followed by puddle-development with an aqueous 2.38 mass % tetramethylammonium hydroxide solution for 60 seconds to obtain resist patterns.

The resist pattern obtained after development was observed with a scanning electron microscope, and the exposure amount at which a line-and-space with a width of 500 nm was obtained was defined as the effective sensitivity.

### <Evaluation of Residue>

The space pattern of a line and space pattern having a line width of 800 nm obtained at the effective sensitivity was observed with a scanning electron microscope, and the space pattern with a residue was evaluated as “x”, and the space pattern without a residue was evaluated as “∘”.

### <Roughness Evaluation by Standing Wave Effect>

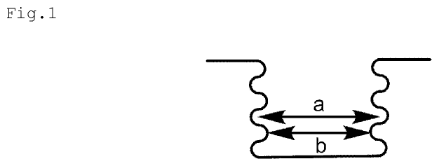

The cross-sectional shape of the line and space having a line width of 500 nm obtained at the effective sensitivity was observed with a scanning electron microscope, and the line widths a and b shown in FIG. 1 were measured, and when the calculated value derived by b/a was less than 0.95, it was regarded as “B”, and when the calculated value was 0.95 or more and 1.00 or less, it was regarded as “A”. a is a line width (maximum value of line width) of the longest portion in the predetermined line, and b is a line width (minimum value of line width) of the shortest portion in the predetermined line.

### <Mask Linearity Evaluation>

In order to examine the mask fidelity, the value of MEF (mask error factor) was obtained from the following formula.

$$MEF = ( CD 800 - CD 500 ) / ( MD 800 - MD 500 )$$

CD800: Dimension (nm) of space pattern with line width of 800 nm obtained in effective sensitivity
CD500: Dimension (nm) of space pattern with line width of 500 nm obtained in effective sensitivity
MD800: 800 nm (dimensions of mask for each pattern)
MD500: 500 nm (dimensions of mask for each pattern)

The case where the MEF value was 1.11 or more or less than 0.89 was defined as “C”, the case where the MEF value was 1.06 or more and less than 1.11 and the case where the MEF value was 0.89 or more and less than 0.94 was defined as “B”, and the case where the MEF value was 0.94 or more and less than 1.06 was defined as “A”.

As the value of MEF is closer to 1, the mask linearity is more favorable.

TABLE 2

| | Resist | | | |
|---|---|---|---|---|
| | composition | Residue | Roughness | MEF |
| Example 1 | Composition 1 | ∘ | A | B |
| Example 2 | Composition 2 | ∘ | A | A |
| Example 3 | Composition 3 | ∘ | A | A |
| Example 4 | Composition 4 | ∘ | A | B |
| Example 5 | Composition 5 | ∘ | A | B |
| Example 6 | Composition 6 | ∘ | A | A |
| Example 7 | Composition 7 | ∘ | A | A |
| Example 8 | Composition 8 | ∘ | A | A |
| Comparative | Comparative | x | B | C |
| Example 1 | Composition 1 | | | |
| Comparative | Comparative | x | B | C |
| Example 2 | Composition 2 | | | |

In Examples 1 to 8, as compared with Comparative Examples 1 and 2, no residue was generated, the roughness due to the standing wave was small, and a resist pattern having a favorable shape could be formed.

The negative resist composition of the present invention is free from residues, has a favorable shape, and is useful for fine processing of semiconductors.

1. A negative resist composition comprising:
a resin (A1) including a structural unit represented by a formula (a2-1) and a structural unit represented by a formula (a2-4);
an acid generator (B);
a crosslinking agent (E); and
an aromatic compound (I) having a molecular weight of 2,000 or less and having three or more phenolic hydroxyl groups, wherein 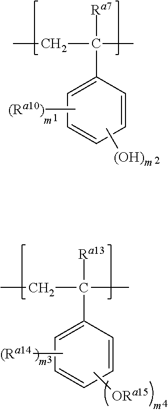
in the formula (a2-1) and the formula (a2-4),
R^{a7} and R^{a13} each independently represent a hydrogen atom or a methyl group,
R^{a10} and R^{a14} each independently represent an alkyl group having 1 to 6 carbon atoms,
R^{a15} represents a hydrocarbon group having 1 to 12 carbon atoms,
m¹ represents an integer of 0 to 4, when m¹ is 2 or more, a plurality of R^{a10} may be same or different from each other,
m² represents an integer of 1 to 4,
provided that a sum of m¹ and m² is 5 or less,
m³ represents an integer of 0 to 4, when m³ is 2 or more, a plurality of R^{a14} may be same or different from each other,
m⁴ represents an integer of 1 to 4, when m⁴ is 2 or more, a plurality of R^{a15} may be same or different from each other, and
provided that a sum of m³ and m⁴ is 5 or less.

2. The negative resist composition according to claim 1, wherein the aromatic compound (I) is a compound represented by a formula (0), wherein 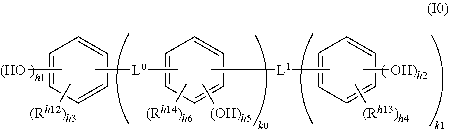
in the formula (I0),
L⁰ and L¹ each independently represent a hydrocarbon group having 1 to 20 carbon atoms and optionally having a substituent, and a methylene group included in the hydrocarbon group may be substituted with an oxygen atom or a carbonyl group,
R^{h12}, R^{h13}, and R^{h14} each independently represent a halogen atom or a hydrocarbon group having 1 to 20 carbon atoms and optionally having a substituent, or R^{h12} and R^{h13}, R^{h12}, and R^{h14}, R^{h13} and R^{h14}, or R^{h12}, R^{h13}, or R^{h14} and L⁰ or L¹ may be bonded to form a ring optionally having a substituent,
k0 represents an integer of 0 to 6, when k0 is 2 or more, a plurality of groups in parentheses may be same or different from each other,
k1 represents an integer of 1 to 6, when k1 is 2 or more, a plurality of groups in parentheses may be same or different from each other,
h1 and h2 each independently represent an integer of 0 to 5,
h5 represents an integer of 0 to 4,
h3 and h4 each independently represent an integer of 0 to 5, when h3 or h4 is 2 or more, a plurality of R^{h12} or R^{h13} may be same or different from each other,
h6 represents an integer of 0 to 4, when h6 is 2 or more, a plurality of R^{h14} may be same or different from each other, and
provided that a sum of h1, h2, and h5 is 3 or more, a sum of h1 and h3 is 5 or less, a sum of h2 and h4 is 5 or less, and a sum of h5 and h6 is 4 or less.

3. The negative resist composition according to claim 1, wherein the aromatic compound (I) is a compound represented by a formula (I1), wherein 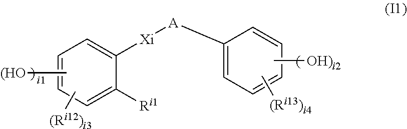
in the formula (I1),
Xi represents a single bond or an oxygen atom,
A represents an alkanediyl group having 1 to 6 carbon atoms and optionally having a substituent, and a methylene group included in the alkanediyl group may be substituted with an oxygen atom or a carbonyl group, provided that when Xi is an oxygen atom, a methylene group bonded to Xi is not substituted with an oxygen atom,
i1 and i2 each independently represent an integer of 0 to 4, provided that a sum of i1 and i2 is 3 or more,
Rⁱ¹² and Rⁱ¹³ each independently represent a halogen atom or an alkyl group having 1 to 12 carbon atoms and optionally having a substituent,
i3 and i4 each independently represent an integer of 0 to 4, when i3 or i4 is 2 or more, a plurality of Rⁱ¹² or Rⁱ¹³ may be the same or different from each other,
Rⁱ¹ represents a hydrogen atom or an alkyl group having 1 to 12 carbon atoms and optionally having a substituent, or when A is an alkanediyl group, Rⁱ¹ may be bonded to A to form a ring optionally having a substituent,
provided that a sum of i1 and i3 is 4 or less, and a sum of i2 and i4 is 5 or less.

4. The negative resist composition according to claim 1, wherein the crosslinking agent (E) is a glycoluril-based crosslinking agent.

5. A method for producing a resist pattern, the method comprising:
(1) applying the negative resist composition according to claim 1 onto a substrate;
(2) drying the applied composition to form a composition layer;
(3) exposing the composition layer; and
(4) heating and developing the exposed composition layer.
